(19) United States
(12) Patent Application Publication
(10) Pub. No.: US 2006/0086461 A1
(43) Pub. Date: Apr. 27, 2006

(54) Etching apparatus and etching method

(75) Inventors: Atsuro Inada, Kawasaki (JP); Kazuhiko Ueno, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/252,805

(22) Filed: Oct. 19, 2005

(30) Foreign Application Priority Data
Oct. 21, 2004 (JP) 2004-307391

(51) Int. Cl. G01L 21/30; H01L 21/306

(52) U.S. Cl. 156/345.33; 216/59; 216/60

(57) ABSTRACT

A wafer processing apparatus 100 involved in an etching apparatus takes part in selective etching of the peripheral portion of a wafer 200. The wafer processing apparatus 100 includes a lower electrode 112 which is a stage on which the wafer 200 is placed, a process gas introducing duct 120 supplying a process gas etching the peripheral portion, and a plurality of etching-interfering gas introducing ducts 118a, 118b, 118c and 118d supplying etching-interfering gas an interfering supply of the process gas to the center of the wafer 200. The etching-interfering gas coming through the plurality of etching-interfering gas introducing ducts 118a to 118d is supplied in a plurality of directions, while being independently controlled in each supply volume.

This application is based on Japanese patent application No. 2004-307391 the content of which is incorporated hereinto by reference.

### BACKGROUND

1. Technical Field

The present invention relates to an etching apparatus and an etching method, and in particular to an etching apparatus and an etching method selectively etching the peripheral portion of a wafer.

2. Related Art

In fabrication processes of semiconductor devices, it is necessary to remove metal or other contaminants adhered to the peripheral portion of wafers, in order to avoid spreading of particles or metal contaminants towards elements formed at the center portion of the wafers.

Japanese Laid-Open Patent Publication No. H7-142449 discloses a technique of limiting discharge planes of upper and lower electrodes of a plasma etching apparatus corresponding to the circumferential surface of the wafer to be etched, and at the same time by blowing an inert gas onto the inner portion of the wafer surface which should not be etched. It is described in this publication that this makes it possible to selectively etch only the circumferential surface of the wafer.

Japanese Laid-Open Patent Publication No. 2001-135712 discloses a vacuum processing apparatus comprising a vacuum chamber in which a wafer is vacuum-processed, a stage disposed in the vacuum chamber and on which the wafer is placed, a plurality of lift-off pins allowed to have a state of being housed in the stage and have a state of being projected upward from the surface of the stage, having an inclined portion inclined so as to allow the upper portion thereof to open outwardly, and a gas blow-out unit blowing a gas upwardly out from the surface of the stage so as to make the wafer float.

Japanese Laid-Open Patent Publication No. H11-186234 discloses an etching apparatus used for plasma-assisted anisotropic etching, configured having a cover provided on a lower electrode so as to cover the region other than a region in which a base is placed, and pressing units pressing the cover onto four divided side faces of the base. The publication describes that the configuration can reduce difference in surface potential between the base and the cover, and can thereby improve uniformity in etching rate of the base.

The conventional etching of the peripheral portion of the wafer has, however, been suffering from a problem in that width of removal of the peripheral portion tends to be non-uniform, showing a larger width of removal on one side and a smaller width of removal on the other side. It is therefore anticipated that setting of a larger margin for the width of removal of the peripheral portion may result in an etching excessively proceeds into the central area for element formation. On the other hand, setting of a smaller margin for the width of removal so as to avoid excessive etching of the central area for element formation may result in only an insufficient removal of contaminants and so forth in the peripheral portion.

### SUMMARY OF THE INVENTION

The present inventors considered that the above-described problems should arise because volume of a process gas etching the peripheral portion of the wafer and an etching-interfering gas such as an inert gas blown at the center portion of the wafer, capable of acting on the wafer, could vary by sites, and conceived the present invention as described below.

According to the present invention, there is provided an etching apparatus selectively etching the peripheral portion of a wafer. The etching apparatus includes a stage on which a wafer is placed; a process gas supply port through which a process gas for etching the peripheral portion is supplied; and an etching-interfering gas supply port through which an etching-interfering gas interfering supply of the process gas to the center of the wafer is supplied. Here, at least either of the process gas supply port and the etching-interfering gas supply port is provided in a multiple way, so as to supply the gas through the plurality of supply ports in a plurality of directions, and so as to independently control supply volume of the gas from the plurality of supply ports.

The etching apparatus herein can be configured as a dry etching apparatus.

The conventional apparatus has only one each supply port supplying therethrough the process gas etching the peripheral portion of the wafer, and supplying the etching-interfering gas blown onto the center portion of the wafer, so that volume of the gas could not be regulated if the amount of gas acting on the wafer differed by sites. This would be causative of variation in the width of removal of the peripheral portion. Whereas the etching apparatus of the present invention, having at least either of the process gas supply port and the etching-interfering gas supply port is provided in a multiple way, so as to allow independent control of the volume of the gas supplied through such plurality of supply ports, makes it possible to equalize the width of removal of the peripheral portion of the wafer, by controlling the supply volume of the gas, even if the volume of gas acting on the wafer differs by sites.

Even for an exemplary case where only a single process gas supply port is provided, it is made possible to regulate the volume of process gas acting on the wafer by controlling flow rate of etching-interfering gas as being varied by sites, and thereby to equalize the width of removal of the peripheral portion. It is also made possible to equalize the etching rate, by providing a plurality of process gas supply ports, and by independently controlling the supply volume of the process gas through such plurality of supply ports.

Even in another exemplary case where only a single etching-interfering gas supply port is provided, it is also made possible to equalize the width of removal of the peripheral portion, by controlling flow rate of the process gas as being varied by sites.

It is still made possible to carry out more precise adjustment and to equalize the width of removal of the peripheral portion, by providing both of the etching-interfering gas supply port and the process gas supply port in multiple ways, and by controlling the flow rates of both of the etching-interfering gas and process gas as being differed by sites.

According to the present invention, an etching apparatus selectively etching the peripheral portion of a wafer is stably equalized in the width of removal of the peripheral portion.

### BRIEF DESCRIPTION OF THE DRAWINGS

The above and other objects, advantages and features of the present invention will be more apparent from the following description taken in conjunction with the accompanying drawings, in which:

FIG. 1 is a drawing schematically showing a configuration of an etching apparatus of an embodiment;

FIG. 2 is a flow chart showing procedures by which a wafer is processed in the etching apparatus of the embodiment;

FIG. 3 is a sectional view showing a configuration of a wafer processing apparatus;

FIG. 4 is a drawing schematically showing the top surface of the wafer processing apparatus shown in FIG. 3;

FIG. 5 is a sectional view showing another exemplary configuration of the wafer processing apparatus;

FIG. 6 is a drawing schematically showing the top surface of the wafer processing apparatus shown in FIG. 5;

FIG. 7 is a drawing schematically showing a configuration of the etching apparatus of another embodiment;

FIG. 8 is a flow chart showing procedures of a control unit in the embodiment;

FIG. 9 is a sectional view showing a configuration of the wafer processing apparatus in still another embodiment;

FIG. 10 is a schematic top view of the wafer processing apparatus shown in FIG. 9;

FIG. 11 is a schematic view showing a successful adjustment of the width of removal of the peripheral portion of a wafer by controlling supply volume of a process gas;

FIG. 12 is a sectional view showing a configuration of the wafer processing apparatus in still another embodiment;

FIGS. 13A and 13B are top views schematically showing an alignment mechanism of the wafer processing apparatus in the embodiment;

FIG. 14 is a top view schematically showing a wafer placed on the wafer processing apparatus shown in FIG. 12;

FIG. 15 is a flow chart showing procedures of wafer processing in the etching apparatus in the embodiment;

FIG. 16 is a sectional view showing a configuration of the wafer processing apparatus in still another embodiment;

FIG. 17 is a schematic top view showing a configuration of the wafer processing apparatus shown in FIG. 16;

FIG. 18 is a drawing showing flow rates of N₂ in Examples;

FIGS. 19A and 19B are drawings schematically showing results of Examples;

FIG. 20 is a drawing showing results of Examples; and

FIG. 21 is a top view schematically showing a wafer placed on the wafer processing apparatus.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The following paragraphs will describe embodiments of the present invention referring to the attached drawings. Any similar constituents appear in all drawings will be given with the same reference numerals, so as to occasionally allow omission of repetitive explanation.

In the embodiments of the present invention, the etching apparatus is used for selective etching of the peripheral portion of a wafer. The etching apparatus includes a lower electrode as a stage on which a wafer is placed, a process gas introducing duct supplying a process gas etching the peripheral portion, and an etching-interfering gas introducing duct supplying an etching-interfering gas interfering supply of the process gas to the center portion of the wafer. The etching-interfering gas introducing duct and the process gas introducing duct can be provided in an upper electrode. At least either one of the process gas supply port and the etching-interfering gas supply port is provided in a multiple way, so as to supply the gas through the plurality of supply ports in a plurality of directions, and so as to independently control supply volume of the gas from the plurality of supply ports.

### First Embodiment

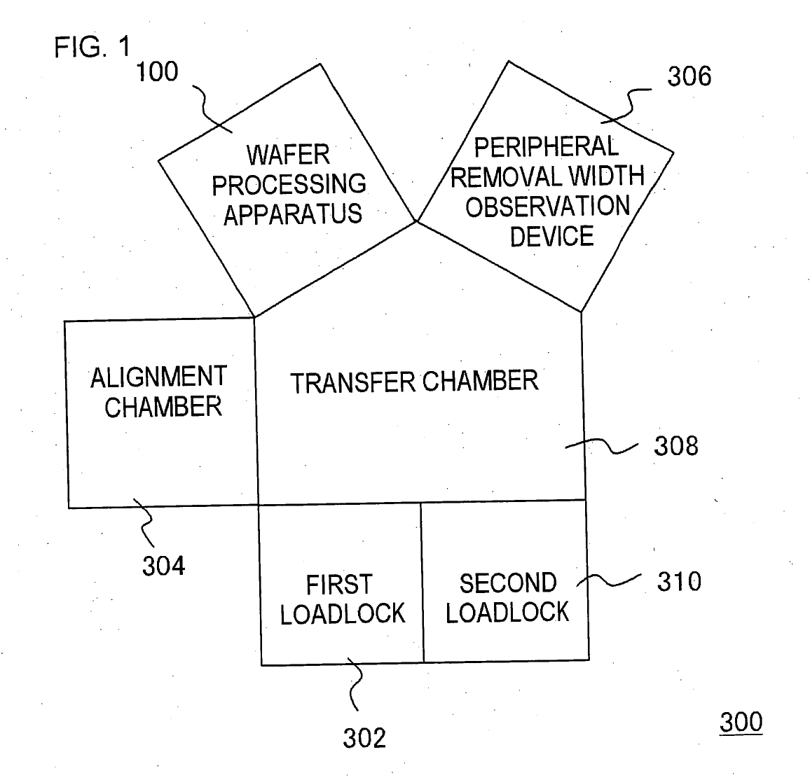

FIG. 1 is a drawing schematically showing a configuration of an etching apparatus of a first embodiment.

The etching apparatus 300 of the first embodiment is intended for plasma etching of the peripheral portion of a wafer. The etching apparatus 300 includes a wafer processing apparatus 100, a first loadlock 302, an alignment chamber 304, a peripheral removal width observation unit 306, a transfer chamber 308, and a second loadlock 310. These constituents are integrated in an all-in-one manner. A wafer is transferred via the transfer chamber 308, from the first loadlock 302 or the second loadlock 310, and among the alignment chamber 304, the wafer processing apparatus 100 and the peripheral removal width observation unit 306, and again to the first loadlock 302 or the second loadlock 310.

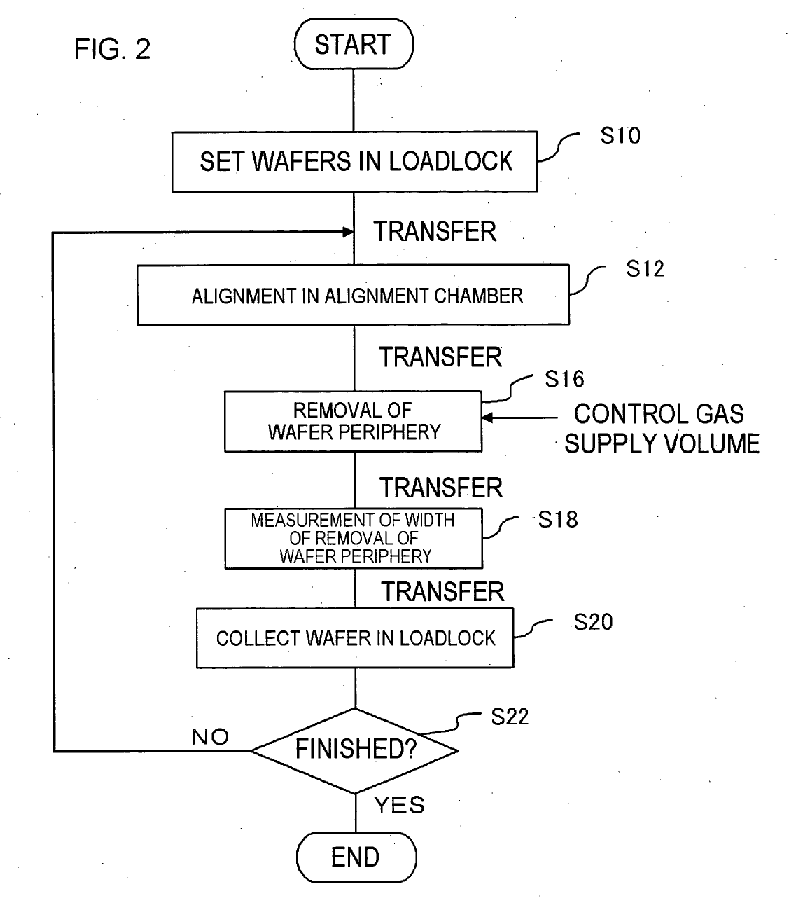

FIG. 2 is a flow chart showing procedures of the wafer processing in the etching apparatus 300 in this embodiment. The procedures will be explained referring also to FIG. 1.

First, a plurality of wafers are set to the first loadlock 302 or the second loadlock 310 (S10). Next, a single wafer is transferred from the first loadlock 302 or the second loadlock 310 to the alignment chamber 304 so as to be aligned therein (S12). The alignment in the alignment chamber 304 takes place referring to a notch of the wafer. The wafer thus aligned in the alignment chamber 304 is then transferred to the wafer processing apparatus 100, and therein the peripheral portion of the wafer is etched (S16). In this embodiment, supply volume of the gas is controlled in this process.

Next, the wafer having the peripheral portion thereof etched in the wafer processing apparatus 100 is transferred to the peripheral removal width observation unit 306, where the width of removal of the peripheral portion of the wafer is measured (S18). The wafer is then transferred out from the peripheral removal width observation unit 306 and back into the other loadlock 302 or 310, and collected therein (S20). These procedures are repeated until all wafers set in the first loadlock 302 or the second loadlock 310 are processed, and after completion of all wafers (YES in S22), the procedures come to the end.

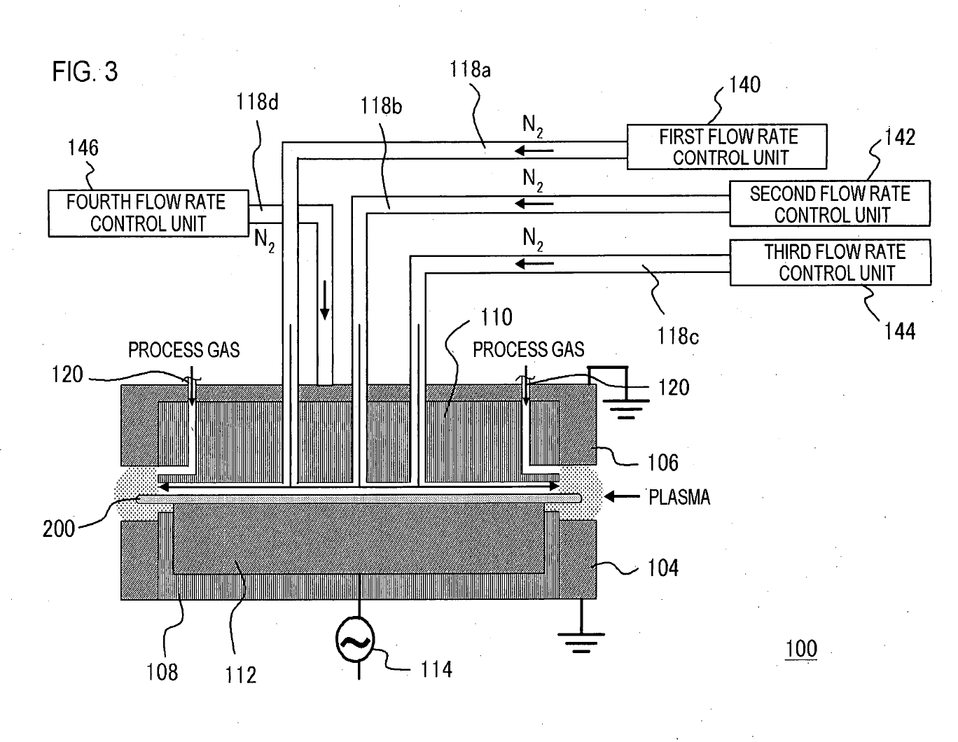

FIG. 3 is a sectional view showing a configuration of the wafer processing apparatus 100.

The wafer processing apparatus 100 herein is of the parallel flat-plate type. The wafer processing apparatus 100 includes a lower electrode 112 connected to a high-frequency power source 114, a grounded upper electrode 106, an earth electrode 104 provided around the lower electrode 112, an upper ceramic 110 provided between the upper electrode 106 and the lower electrode 112, and a lower ceramic 108 provided between the lower electrode 112 and the earth electrode 104.

The lower electrode 112 herein functions as a stage, on which a wafer 200 is placed. The upper ceramic 110 is disposed as covering the central upper region of the wafer, so as to prevent a plasma from contacting with the center portion of the wafer 200 placed on the lower electrode 112. The lower electrode 112 is configured as having a diameter smaller than that of the wafer 200. This makes it possible to allow the plasma during plasma etching to extend behind the back peripheral portion of the wafer 200, and to remove contaminants, films or the like adhered on the back peripheral portion of the wafer 200.

The wafer processing apparatus 100 further includes a process gas introducing duct 120 which leads to the peripheral portion of the wafer 200 placed on the lower electrode 112, and a plurality of ducts of a first etching-interfering gas introducing duct 118a, a second etching-interfering gas introducing duct 118b, a third etching-interfering gas introducing duct 118c, and a fourth etching-interfering gas introducing duct 118d, each of which leads to the center portion of the wafer 200.

The wafer processing apparatus 100 still further includes a first flow rate control unit 140, a second flow rate control unit 142, a third flow rate control unit 144 and a fourth flow rate control unit 146, respectively controlling the supply volume of the etching-interfering gas supplied through the plurality of etching-interfering gas introducing ducts 118a to 118d. Each of the first flow rate control unit 140, the second flow rate control unit 142, the third flow rate control unit 144 and the fourth flow rate control unit 146 can typically be configured by a mass flow controller and a valve. The etching-interfering gas may be an inert gas such as N₂ (nitrogen). In this embodiment, the etching-interfering gas is N₂. By supplying the etching-interfering gas to the center portion of the wafer 200 as described in the above, the process gas can be supplied only to the peripheral portion of the wafer 200. This makes it possible to selectively remove the contaminants and films adhered on the peripheral portion of the wafer 200. The process gas may be an etching gas. The etching gas may differ depending on types of an object to be etched, wherein a fluorocarbon-base gas may be used for etching of a silicon oxide film, for example.

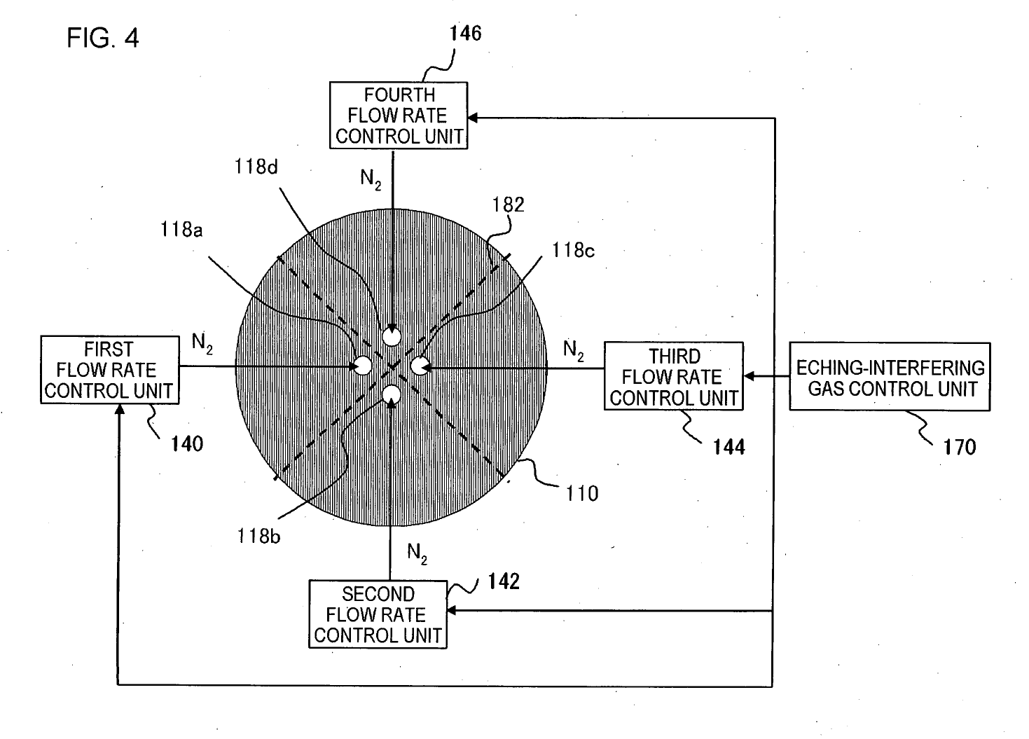

FIG. 4 is a drawing schematically showing the top surface of the upper ceramic 110 of the wafer processing apparatus 100 shown in FIG. 3.

The wafer processing apparatus 100 further includes an etching-interfering gas control unit 170 controlling the first flow rate control unit 140, the second flow rate control unit 142, the third flow rate control unit 144 and the fourth flow rate control unit 146. The etching-interfering gas control unit 170 independently controls volume of the etching-interfering gas supplied through the first flow rate control unit 140, the second flow rate control unit 142, the third flow rate control unit 144 and the fourth flow rate control unit 146. A partition unit 182, although not shown in FIG. 3, may also be provided between the upper ceramic 110 and the lower electrode 112. In this embodiment, the partition unit 182 is disposed so as to radially quadriasect the upper ceramic 110. The partition unit 182 is preferably configured so as not to contact with the wafer 200 placed on the lower electrode 112. The etching-interfering gas discharged from the plurality of etching-interfering gas introducing ducts 118a to 118d is introduced into each region partitioned by the partition unit 182. This makes it possible to control volume of the gas to be introduced for every region, and to equalize the width of removal of the peripheral portion.

Because the wafer processing apparatus 100 in this embodiment has a plurality of flow rate control units, and the volume of introduction of the gas through the plurality of etching-interfering gas introducing ducts can be controlled in an independent manner, it is made possible to equalize the width of removal of the peripheral portion.

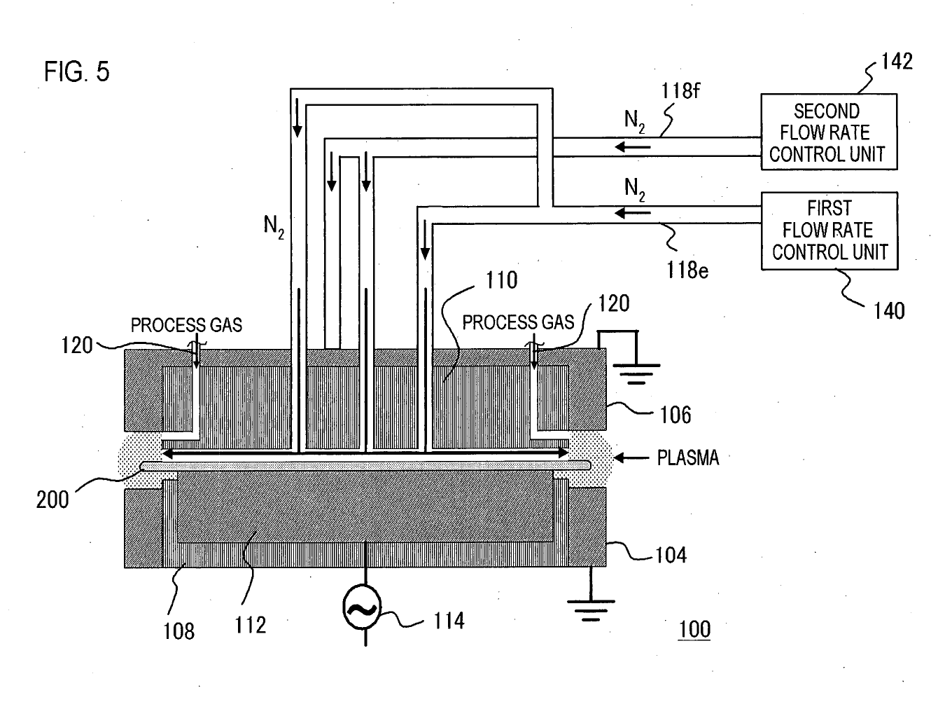

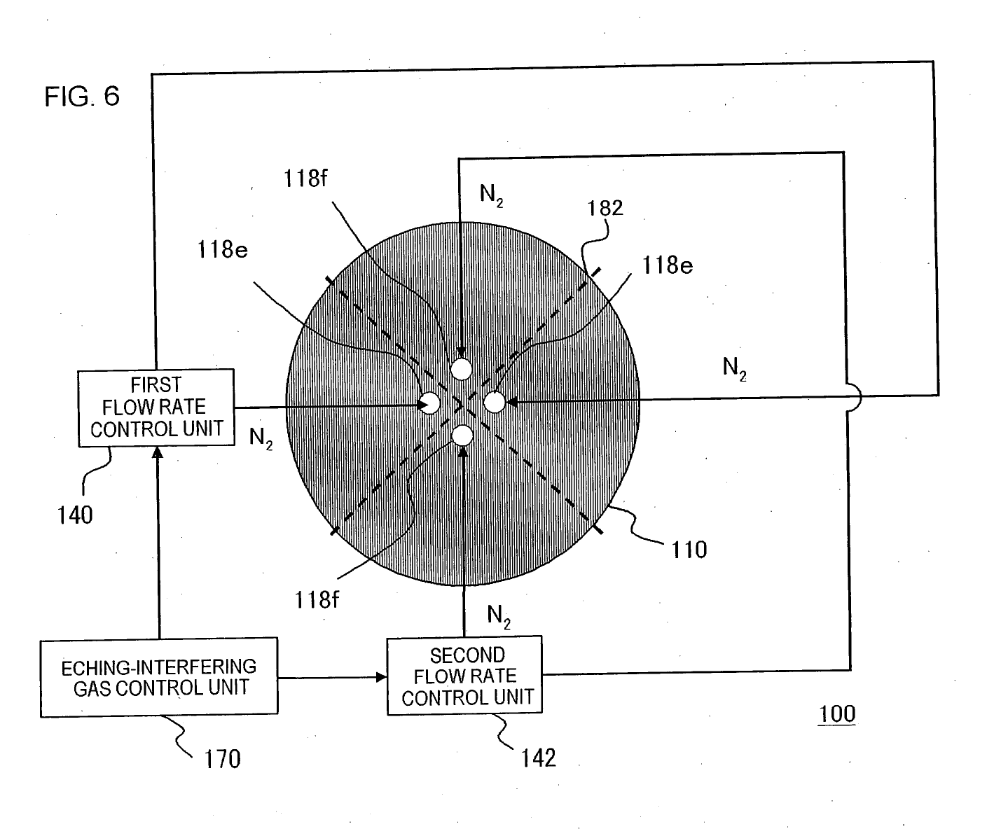

The above-described example dealt with a configuration in which a single gas supply port corresponds to a single flow rate control unit, whereas another possible configuration may have two or more gas supply ports provided with respect to a single flow rate control unit. The example is shown in FIG. 5 and FIG. 6.

The wafer processing apparatus 100 may also be configured as having two ducts, that are, a sixth etching-interfering gas introducing duct 118f and a fifth etching-interfering gas introducing duct 118e. In this configuration, each of the sixth etching-interfering gas introducing duct 118f and the fifth etching-interfering gas introducing duct 118e may be configured as being branched in two, so as to make it possible to introduce the etching-interfering gas from four sites in the upper ceramic 110. Supply volume of the etching gas supplied through the fifth etching-interfering gas introducing duct 118e and the sixth etching-interfacing gas introducing duct 118f are controlled by the first flow rate control unit 140 and the second flow rate control unit 142, respectively.

Each of the fifth etching-interfering gas introducing duct 118e and the sixth etching-interfering gas introducing duct 118f shown in FIG. 5 and FIG. 6 was configured so that two individual branched ducts are disposed in the opposed regions, but it is also allowable to dispose two branched ducts of the fifth etching-interfering gas introducing duct 118e and the sixth etching-interfering gas introducing duct 118f respectively in the adjacent regions.

Also the above-described configuration is successful in independently controlling the amount of introduction of the etching-interfering gas from the plurality of etching-interfering gas introducing ducts, and can reduce non-uniformity in the width of removal of the peripheral portion of the wafer 200 only by a simple configuration.

The wafer processing apparatus 100 may also include a plurality of etching-interfering gas introducing ducts and a plurality of flow rate control units controlling the supply volume therethrough, not being limited to the number of four. For example, the wafer processing apparatus 100 may be configured as having five or more etching-interfering gas introducing ducts. This makes it possible to more finely control the supply volume of the etching-interfering gas, and to make adjustment so as to equalize the width of removal of the peripheral portion of the wafer 200. The wafer processing apparatus 100 may be configured also as comprising two or three etching-interfering gas introducing ducts. Again this also makes it possible to control the supply volume of the etching-interfering gas, and to make adjustment so as to equalize the width of removal of the peripheral portion of the wafer 200.

### Second Embodiment

The second embodiment differs from the first embodiment in that the supply volume of the etching-interfering gas during etching of the wafer to be etched next is controlled based on degree of variation in the width of removal of the peripheral portion of the wafer observed by the peripheral removal width observation unit 306.

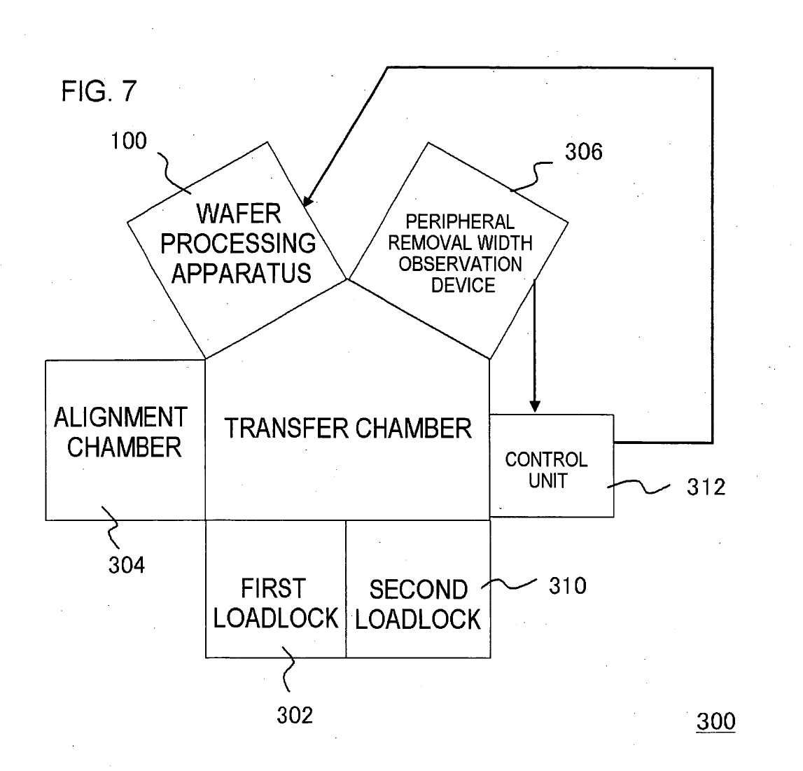

FIG. 7 is a drawing schematically showing a configuration of an etching apparatus of the second embodiment.

The etching apparatus 300 of the second embodiment further includes a control unit 312, in addition to the configuration of the etching apparatus 300 explained in the first embodiment referring to FIG. 1. The control unit 312 calculates displacement of the center of the wafer 200, based on the width of removal of the peripheral portion observed by the peripheral removal width observation unit 306. The control unit 312 transmits thus calculated displacement of the center of the wafer 200 to the wafer processing apparatus 100.

In this embodiment, the etching-interfering gas control unit 170 shown in FIG. 4, upon being transmitted by the control unit 312 (see FIG. 7), controls the supply volume of the etching-interfering gas through the first flow rate control unit 140, the second flow rate control unit 142, the third flow rate control unit 144 and the fourth flow rate control unit 146, based on the displacement of the center of the wafer 200 in the previous processing.

This makes it possible to equalize the width of removal of the peripheral portion of the wafer 200. The adjustment may be made every time a single wafer 200 is processed by the etching apparatus 300, or may be made after processing of every several wafers.

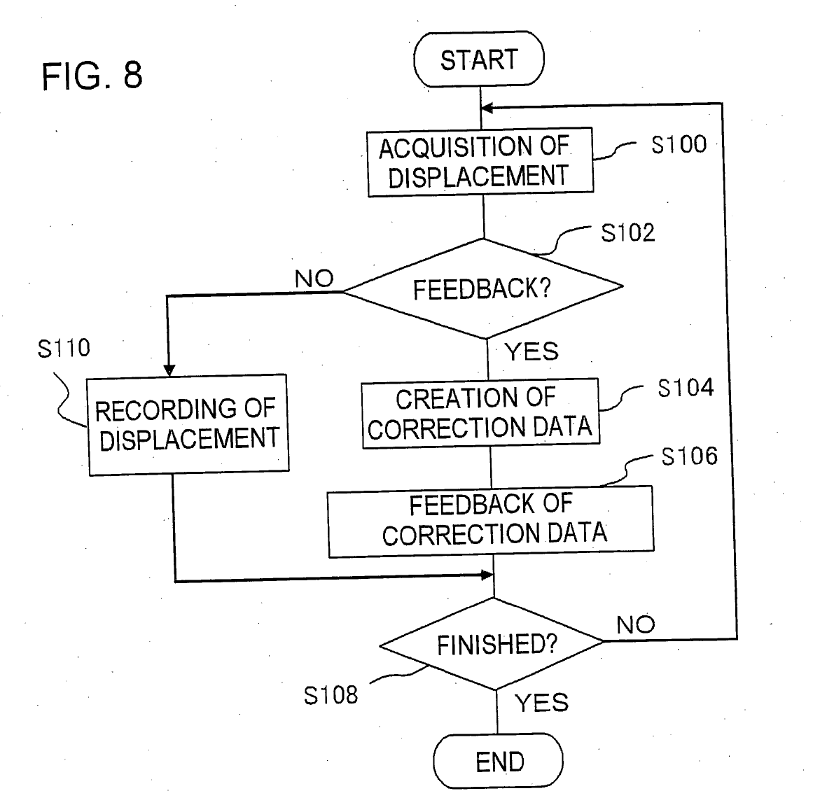

FIG. 8 is a flow chart showing procedures of the processing by the control unit 312 in the second embodiment.

First, the control unit 312 acquires the displacement of the center of the wafer 200 from the peripheral removal width observation unit 306 (S100), and judges whether the dislocation should be fed back to the wafer processing apparatus 100 (S102). For example, the control unit 312 compares the width of removal of the peripheral portion of the wafer 200 obtained from the peripheral removal width observation unit 306 with a reference value stored in the memory unit (not shown) of the control unit 312, and judges whether the peripheral portion of the wafer 200 was appropriately etched. If the peripheral portion of the wafer 200 was judged as being not appropriately etched, a judgment will be such that feedback is necessary (YES in S102).

When the displacement of the center is fed back to the wafer processing apparatus 100 (YES in S102), a correction data is created (S104). The control unit 312 calculates an appropriate flow rate of the etching-interfering gas. Next, the correction data is transmitted to a drive control unit 130 of the wafer processing apparatus 100 (S106). Whether the process should be completed or not is judged (S108), and the process goes back to step S100 if any unprocessed wafers 200 remain in the first loadlock 302 or the second loadlock 310, and the same procedures are repeated. If no feedback is made in step S102 despite the dislocation (NO in S102), the dislocation acquired in step S100 is stored in a predetermined memory unit (S110). The process then goes to step S108, and the similar processing are repeated. If dislocation values relevant to a plurality of wafers 200 are stored in the predetermined memory unit, it is also allowable, for example, to create the correction data by averaging these values. The control unit 312 can also create the correction data based on transition of the dislocation relevant to a plurality of wafers 200.

When completion of all wafers 200 set in the first loadlock 302 or the second loadlock 310 is judged in step S108, the wafers 200 are collected in the other loadlock 302 or 310, and the process is completed (YES in S108).

If the correction data is transmitted to the wafer processing apparatus 100 in step S106, the etching-interfering gas control unit 170 of the wafer processing apparatus 100 controls, based on the correction data, the supply volume of the etching-interfering gas supplied from the first flow rate control unit 140, the second flow rate control unit 142, the third flow rate control unit 144 and the fourth flow rate control unit 146 through the first etching-interfering gas introducing duct 118a, the second etching-interfering gas introducing duct 118b, the third etching-interfering gas introducing duct 118c and the fourth etching-interfering gas introducing duct 118d. This makes it possible to correct variation in the width of removal of the peripheral portion of the wafer 200 ascribable to characteristics and so forth of the wafer processing apparatus 100.

Because, in the above-described process, the supply volume of the etching-interfering gas can independently be controlled by sites depending on the dislocation of the previously-processed wafer 200, it is made possible, for example, to finely adjust the supply volume of the etching-interfering gas to the wafer 200, by taking, for example, fluctuation in the plasma generation zone into consideration. It is also allowable to uniformly correct the width of removal of the peripheral portion of the wafer 200, even if non-uniformity in the width of removal of the peripheral portion should occur due to any possible characteristics of the apparatus.

### Third Embodiment

The third embodiment differs from the first and second embodiments in that the flow volume of the process gas is controlled together with the flow volume of the etching-interfering gas. Also in the third embodiment, the etching apparatus 300 has a configuration similar to that described in the first embodiment referring to FIG. 1. The etching apparatus 300 may be configured also as being similar to that explained in the second embodiment referring to FIG. 7. In the third embodiment, any constituents similar to those explained in the first embodiment and the second embodiment will be given with the similar reference numerals, so as to occasionally allow omission of repetitive explanation.

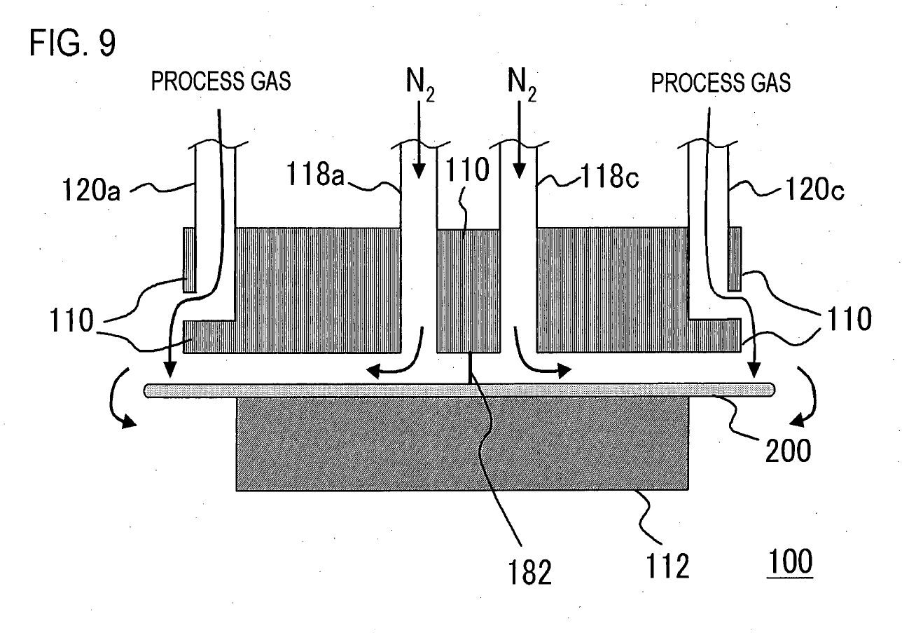

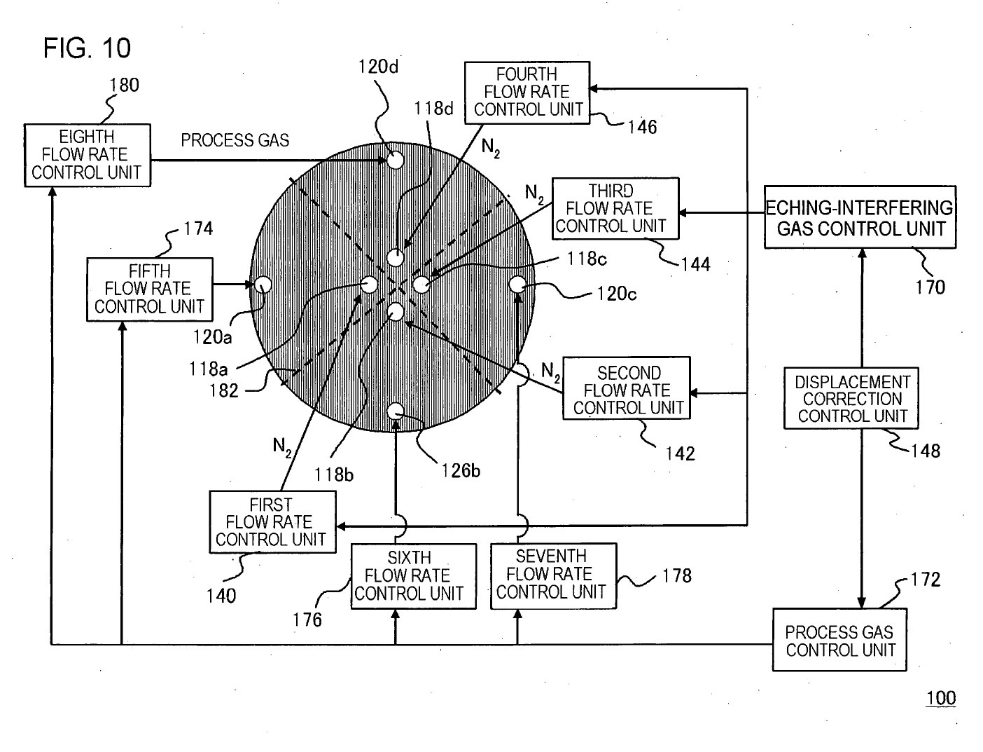

FIG. 9 is a sectional view showing a configuration of the wafer processing apparatus 100 in the third embodiment. FIG. 10 is a schematic top view showing a configuration of the upper ceramic 110 of the wafer processing apparatus 100 shown in FIG. 9.

In addition to the configuration of the wafer processing apparatus 100 explained in the first embodiment referring to FIG. 3 and FIG. 4, the wafer processing apparatus 100 further includes a first process gas introducing duct 120a, a second process gas introducing duct 120b, a third process gas introducing duct 120c and a fourth process gas introducing duct 120d, each of which leads to the peripheral portion of the wafer 200 placed on the lower electrode 112. FIG. 9 shows only constituents necessary for the explanation, and does not show the upper electrode 106, the lower ceramic 108, the earth electrode 104 and so forth, but the wafer processing apparatus 100 in the third embodiment also includes these constituents similarly to as in the configuration shown in FIG. 3.

As shown in FIG. 10, the wafer processing apparatus 100 further includes a fifth flow rate control unit 174, a sixth flow rate control unit 176, a seventh flow rate control unit 178 and an eighth flow rate control unit 180, each of which controls the supply volume of the process gas supplied through the plurality of process gas introducing ducts 120a to 120d. Each of the fifth flow rate control unit 174, the sixth flow rate control unit 176, the seventh flow rate control unit 178 and the eighth flow rate control unit 180 can typically be configured by a mass flow controller and a valve.

The partition unit 182 herein may be provided between the upper ceramic 110 and the lower electrode 112, so as to introduce the gases discharged from the etching-interfering gas introducing ducts 118a to 118d, and from the process gas introducing ducts 120a to 120d into the respective regions partitioned by the partition unit 182. This makes it possible to control, by regions, the volume of introduction of the etching-interfering gas and the process gas, and to make adjustment so as to equalize the width of removal of the peripheral portion.

In this embodiment, the process gas control unit 172 controls the fifth flow rate control unit 174, the sixth flow rate control unit 176, the seventh flow rate control unit 178 and the eighth flow rate control unit 180, so as to independently control the supply volume of the process gas supplied therethrough. A displacement correction control unit 148 controls the etching-interfering gas control unit 170 and the process gas control unit 172.

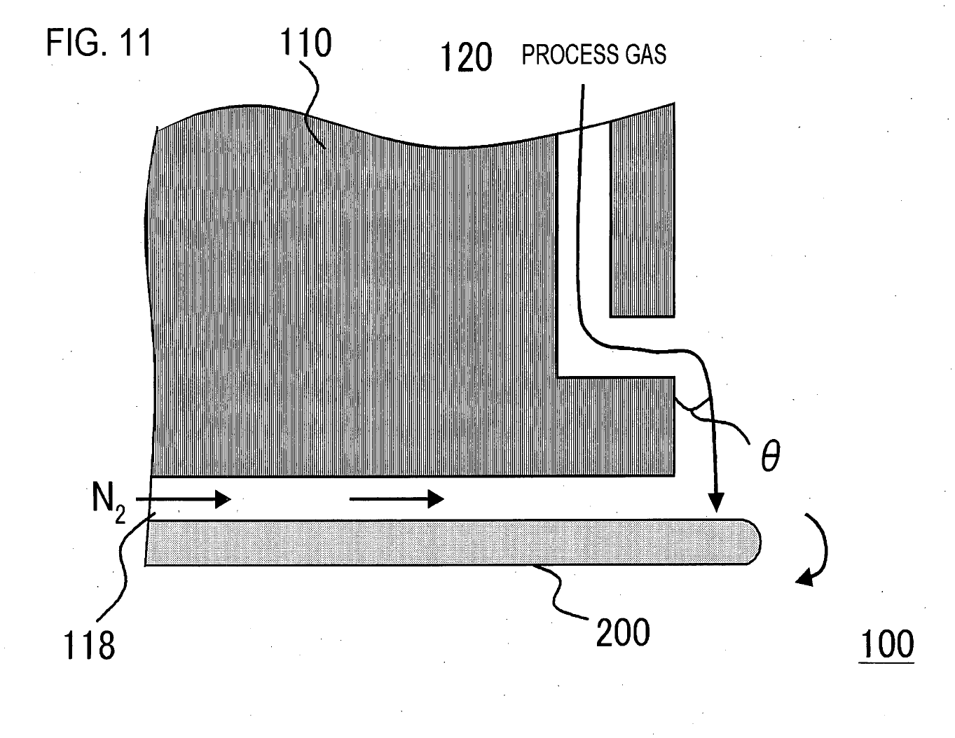

FIG. 11 is a schematic drawing showing an adjustment of the width of removal of the peripheral portion of the wafer 200 by controlling the supply volume of the process gas in the third embodiment.

As shown in the drawing, angle θ of supply of the process gas supplied to the wafer 200 is variable by controlling the supply volume of the process gas through the process gas introducing duct 120. It is therefore made possible to adjust the width of removal of the peripheral portion of the wafer 200, by appropriately setting such angle of supply.

The wafer processing apparatus 100 of the third embodiment can yield effects similar to those described in the first and the second embodiments. Because the supply volume of the etching-interfering gas and the supply volume of the process gas can be corrected at the same time, it is made possible to more finely control the uniformity in the width of removal of the peripheral portion of the wafer 200, by taking, for example, fluctuation in the plasma generation zone into consideration. It is also made possible to equalize the etching rate by correcting the supply volume of the process gas.

### Fourth Embodiment

A forth embodiment differs from the first embodiment in that the wafer 200 is aligned in the wafer processing apparatus 100 prior to the etching with the flow rate of the etching-interfering gas is controlled. Also in the fourth embodiment, the etching apparatus 300 has a configuration similar to that explained in the first embodiment referring to FIG. 1. In the fourth embodiment, any constituents similar to those explained in the first embodiment and the second embodiment will be given with the similar reference numerals, so as to allow omission of repetitive explanation on occasions.

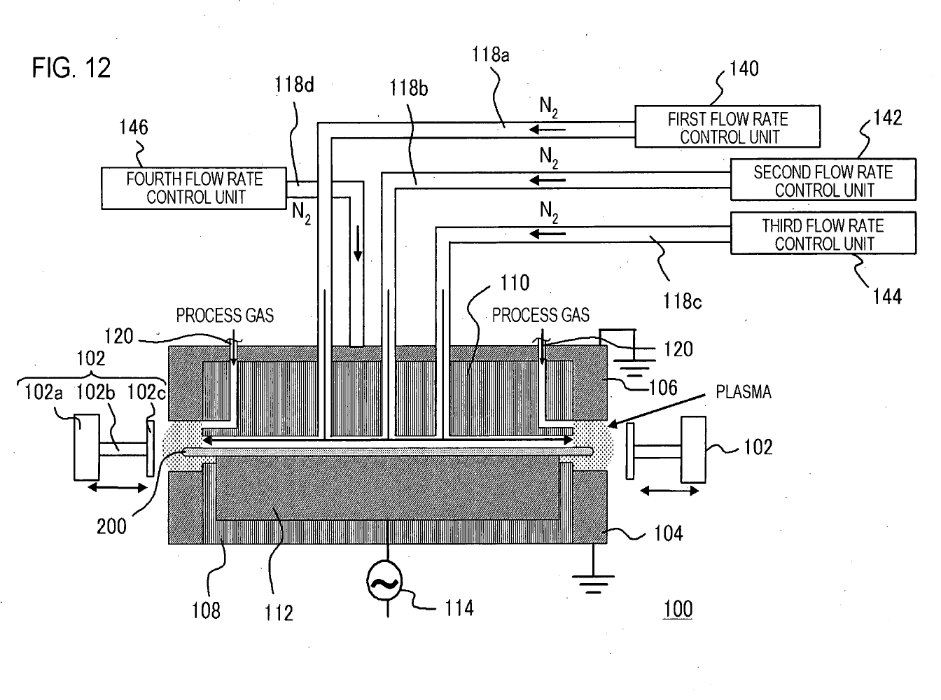

FIG. 12 is a sectional view showing a configuration of the wafer processing apparatus 100 in the fourth embodiment.

In addition to the configuration of the wafer processing apparatus 100 explained in the first embodiment referring to FIG. 3 and FIG. 4, the wafer processing apparatus 100 further has a movable alignment mechanism 102 which includes a drive unit 102a, an arm unit 102b and a guard block 102c. This makes it possible to align the wafer 200 at a standard position even if it is loaded into the wafer processing apparatus 100 in a displaced manner. The standard position herein means a position where the center of the lower electrode 112 and the center of the wafer 200 coincide. Although not shown in the drawing, the wafer processing apparatus 100 may include the etching-interfering gas control unit 170 (see FIG. 4) independently controlling the first flow rate control unit 140, the second flow rate control unit 142, the third flow rate control unit 144 and the fourth flow rate control unit 146.

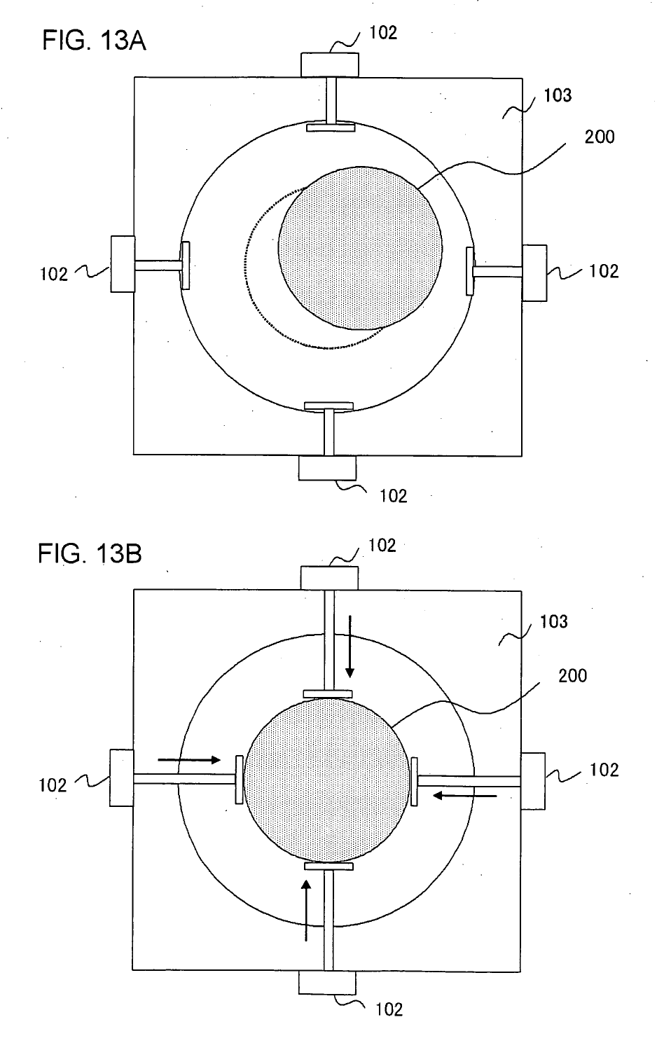

FIGS. 13A and 13B are top views schematically showing the alignment mechanism of the wafer processing apparatus 100 in the fourth embodiment. FIG. 13A shows a state in which the wafer 200 transferred from the alignment chamber 304 (see FIG. 1) is disposed as being shifted from the standard position. FIG. 13B shows a state in which the wafer 200 is aligned at the standard position.

The wafer 200 is transferred by an arm (not shown) provided to the transfer chamber 308, from the alignment chamber 304 to the wafer processing apparatus 100. The wafer 200 is then transferred from the arm onto three pins (not shown) in the wafer processing apparatus 100, and placed on the lower electrode 112.

The alignment mechanism 102 aligns the wafer 200 placed on the lower electrode 112. In the alignment mechanism 102, the drive unit 102a is provided to an inner wall 103 of the wafer processing apparatus 100 besides the lower electrode 112. The arm unit 102b is stretchable in the horizontal direction with the aid of the drive unit 102a, so as to move the guard block 102c between the inner wall 103 (state shown in FIG. 13A) and a predetermined position (state shown in FIG. 13B, for example) in the vicinity of the standard position. The guard block 102c is configured as being contactable with the wafer 200. The drive unit 102a drives the arm unit 102b so that the guard block 102c is positioned at the inner wall 103 when the wafer 200 is loaded into the wafer processing apparatus 100. After the wafer 200 is placed on the lower electrode 112, the drive unit 102a drives the arm unit 102b so as to position the guard block 102c at the standard wafer position. The alignment mechanism 102 is thus aligned at the standard wafer position. After the alignment, the drive unit 102a drives the arm unit 102b so that the guard block 102c is positioned at the inner wall 103. In the fourth embodiment, each of a plurality of drive units 102a of the alignment mechanisms 102 independently drives the arm unit 102b and the guard block 102c.

For example, the drive unit 102a of each alignment mechanism 102 can be configured as extending and retracting the arm unit 102b by a predetermined length, so as to move the guard block 102c to a predetermined position.

The guard block 102c may be configured using a plastic material such as Teflon (Du Pont, registered trademark) and Vespel (Du Pont, registered trademark), or a ceramic. In particular, the guard block 102c is preferably configured by a plastic material such as Vespel. This makes it possible to reduce impact on the wafer 200 when the guard block 102c comes into contact with the wafer 200. It is also preferable that the guard block 102c has a linear or flat surface which comes into contact with the wafer 200. This is successful in precisely aligning the wafer 200.

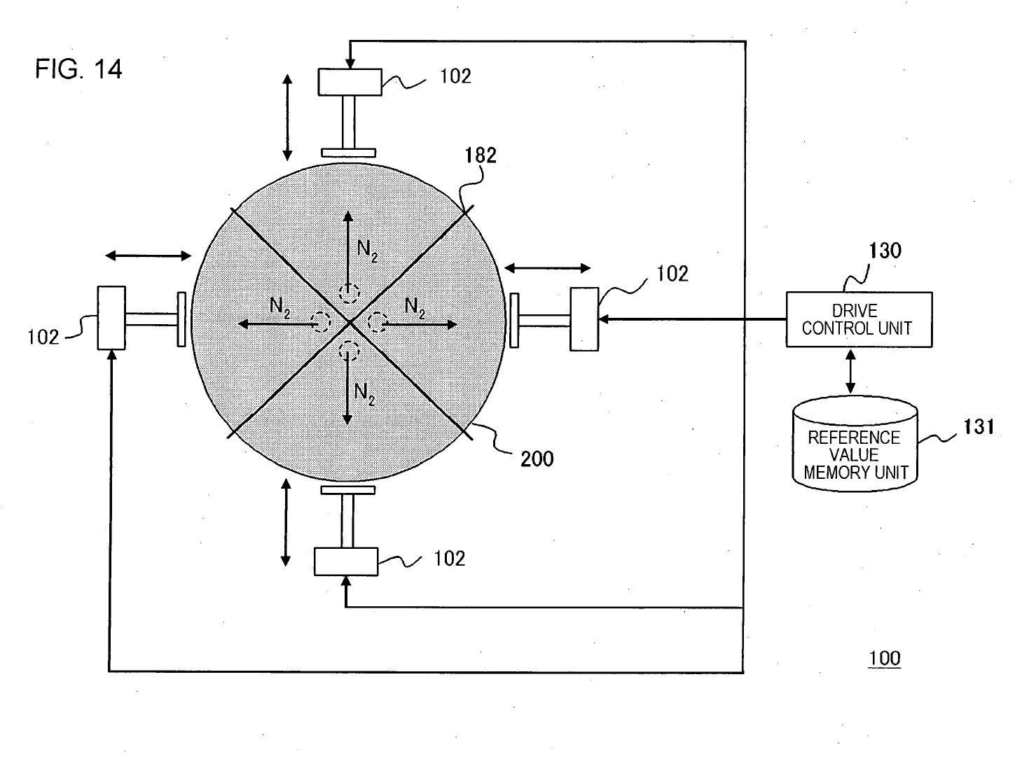

FIG. 14 is a schematic top view of the wafer 200 placed on the wafer processing apparatus 100 shown in FIG. 12.

The wafer processing apparatus 100 includes the drive control unit 130 independently controlling each of the drive units 102a of a plurality of the alignment mechanisms 102, and a reference value memory unit 131 storing a reference value of stroke of each drive unit 102a of each alignment mechanism 102 extending and retracting the arm unit 102b. The drive control unit 130 acquires the stroke by which each drive unit 102a of each alignment mechanism 102 extends and retracts the arm unit 102, referring to the reference value memory unit 131, and controls the drive unit 102a. This makes it possible to move each alignment mechanism 102 by a predetermined stroke. Although it is not shown in the drawing, the wafer processing apparatus 100 may include the etching-interfering gas control unit 170 as shown in FIG. 4 for example.

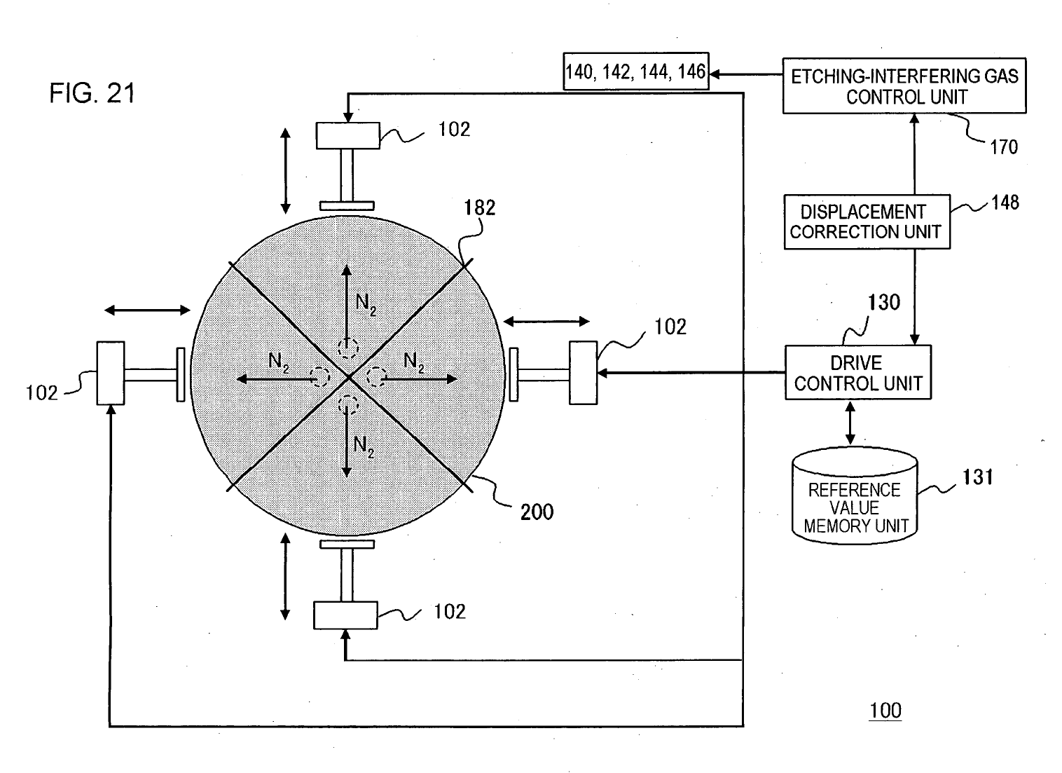

The wafer processing apparatus 100 may further includes a displacement correction control unit 148 controlling the drive control unit 130 and the etching-interfering gas control unit 170 as shown in FIG. 21. In this configuration, the displacement correction control unit 148, upon being transmitted from the control unit 312 (see FIG. 7), controls the etching-interfering gas control unit 170 and the drive control unit 130, based on the displacement of the center of the wafer 200 caused in the previous processing. The drive control unit 130 controls the stroke of the alignment mechanism 102, based on the displacement of the center of the wafer 200 caused in the previous processing. The etching-interfering gas control unit 170 controls the supply volume of the etching-interfering gas supplied through the first flow rate control unit 140, the second flow rate control unit 142, the third flow rate control unit 144 and the fourth flow rate control unit 146, based on the displacement of the center of the wafer 200 caused in the previous processing. This makes it possible to accurately align the wafer 200 and to adjust the supply volume of the gas. This processing may be made every time a single wafer 200 is processed by the etching apparatus 300, or may be made after processing of every several wafers.

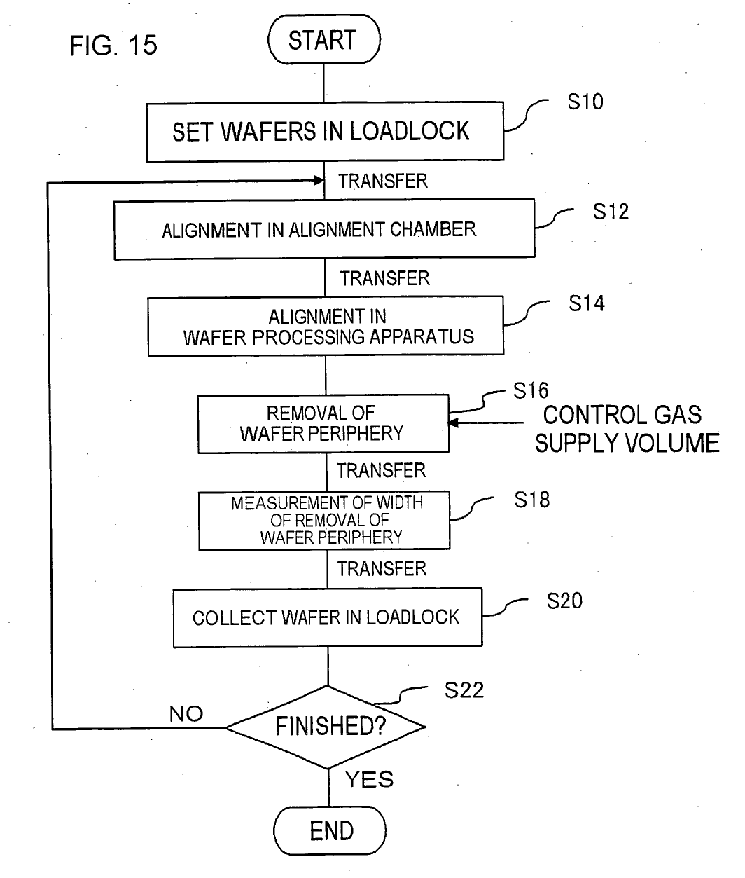

FIG. 15 is a flow chart showing procedures of the wafer processing in the etching apparatus 300 of the fourth embodiment.

First, the wafers are set in the first loadlock 302 or the second loadlock 310 (S10). Next, a single wafer is transferred from the first loadlock 302 or the second loadlock 310 to the alignment chamber 304, and is aligned in the alignment chamber 304 (S12). Then the wafer aligned in the alignment chamber 304 is transferred to the wafer processing apparatus 100, and is aligned in the wafer processing apparatus 100 (S14). The wafer is then subjected to removal of the peripheral portion thereof in the wafer processing apparatus 100 (S16). In the fourth embodiment, the supply volume of the gas is controlled in this process.

Next, the wafer having the peripheral portion etched therefrom in the wafer processing apparatus 100 is then transferred to the peripheral removal width observation unit 306, where measurement is made on the width of removal of the peripheral portion of the wafer (S18). The wafer is then transferred from the peripheral removal width observation unit 306 back into the other loadlock 302 or 310, and is recovered therein (S20). These processes are repeated until all wafers set in the first loadlock 302 or the second loadlock 310 are processed, and the process comes to the end when all wafers set in the first loadlock 302 or the second loadlock 310 are processed (YES in S22).

The fourth embodiment is also successful in obtaining effects similar to those explained in the first and second embodiments. Because displacement of the wafer 200 and the supply volume of the etching-interfering gas can be corrected at the same time, it is made possible, for example, to more finely control the uniformity in the width of removal of the peripheral portion of the wafer 200, by taking, for example, fluctuation in the plasma generation zone into consideration.

### Fifth Embodiment

The fifth embodiment differs from the third embodiment in that the flow volumes of each of the etching-interfering gas and the process gas is controlled, and in that the wafer 200 is aligned before the etching in the wafer processing apparatus 100. Also the etching apparatus 300 in the fifth embodiment has a configuration similar to that explained in the first embodiment referring to FIG. 1. In the fifth embodiment, any constituents similar to those explained in the first to fourth embodiments will be given with the same reference numerals, so as to allow omission of repetitive explanation on occasions.

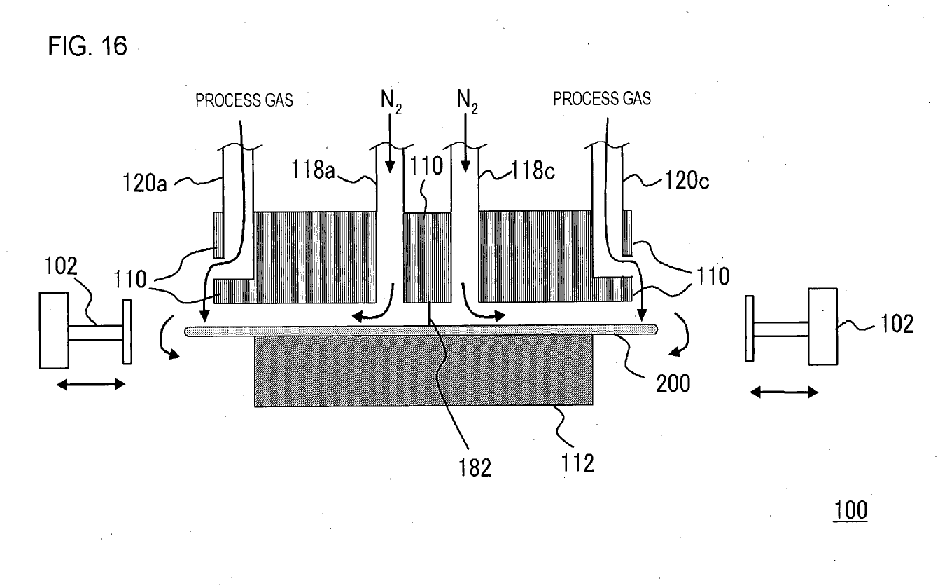

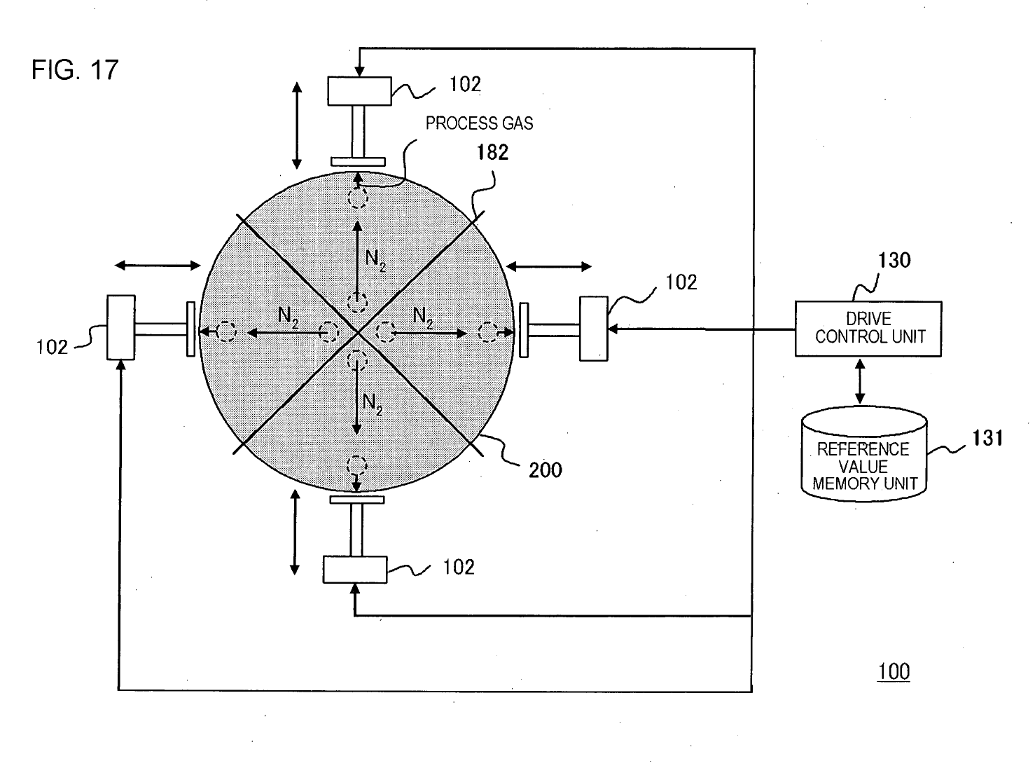

FIG. 16 is a sectional view showing a configuration of the wafer processing apparatus 100 of the fifth embodiment. FIG. 17 is a schematic top view of the wafer 200 placed on the wafer processing apparatus 100 shown in FIG. 16. Although it is not shown in FIG. 16 and FIG. 17, the wafer processing apparatus 100 of this embodiment may have same components as shown in FIG. 10 of the third embodiment. Therefore, the following description will be made with referring to FIG. 10 as well.

In addition to the configuration explained in the fourth embodiment referring to FIG. 12 to FIG. 14, the wafer processing apparatus 100 herein further includes the first process gas introducing duct 120a, the second process gas introducing duct 120b (see FIG. 10), the third process gas introducing duct 120c and the fourth process gas introducing duct 120d (see FIG. 10), all of which lead to the peripheral portion of the wafer 200 placed on the lower electrode 112.

Also the wafer processing apparatus 100 in the fifth embodiment includes, similarly to as shown in FIG. 10, the first flow rate control unit 140, the second flow rate control unit 142, the third flow rate control unit 144, the fourth flow rate control unit 146, the fifth flow rate control unit 174, the sixth flow rate control unit 176, the seventh flow rate control unit 178, the eighth flow rate control unit 180, the etching-interfering gas control unit 170, process gas control unit 172 and the displacement correction control unit 148. The displacement correction control unit 148 controls the etching-interfering gas control unit 170, the process gas control unit 172 and the drive control unit 130.

The fifth embodiment is successful in obtaining effects similar to those explained in the fourth embodiment. Because displacement of the wafer 200, the supply volume of the etching-interfering gas, and the supply volume of the process gas can be corrected at the same time, it is made possible to more finely control the uniformity in the width of removal of the peripheral portion of the wafer 200, by taking, for example, fluctuation in the plasma generation zone into consideration.

### EXAMPLES

### Example 1

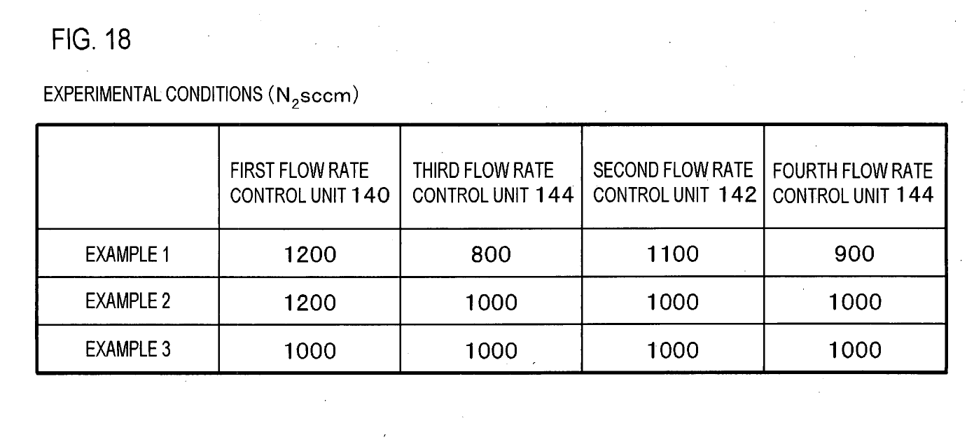

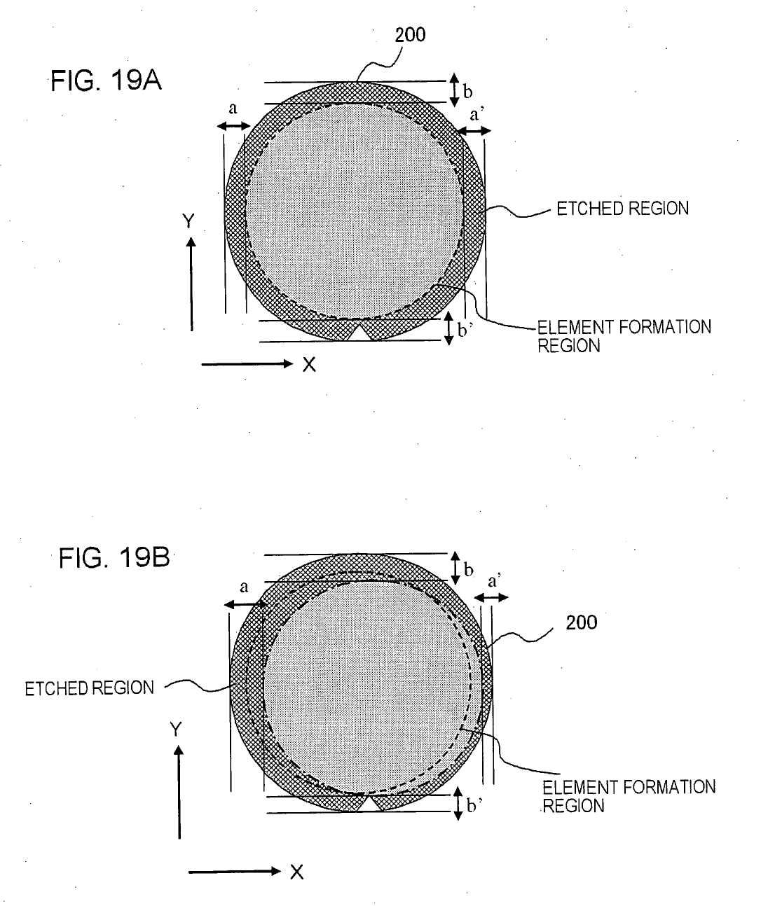

The peripheral portion of the wafer 200, with the notch thereof directed downward, was etched using the wafer processing apparatus 100 explained in the first embodiment referring to FIG. 3 and FIG. 4. In the etching, each of the first flow rate control unit 140, the second flow rate control unit 142, the third flow rate control unit 144 and the fourth flow rate control unit 146 was controlled to thereby adjust the flow rate of N₂ as the etching-interfering gas. FIG. 18 shows the flow rate of N₂. The widths of removal of the edges in the X direction are defined as “a” and “a′”, and the widths of removal of the edges in the Y direction are defined as “b” and “b′” (see FIG. 19A for example).

### Example 2

The peripheral portion of the wafer 200, with the notch thereof directed downward, was etched similarly to as described in Example 1. In the etching, the flow rate of N₂ as the etching-interfering gas was controlled by controlling only the first flow rate control unit 140. The flow rate of N₂ is shown in FIG. 18.

### Example 3

The peripheral portion of the wafer 200, with the notch thereof directed downward, was etched similarly to as described in Example 1. In the etching, control was made on none of the first flow rate control unit 140, the second flow rate control unit 142, the third flow rate control unit 144 and the fourth flow rate control unit 146. The flow rate of N₂ is shown in FIG. 18.

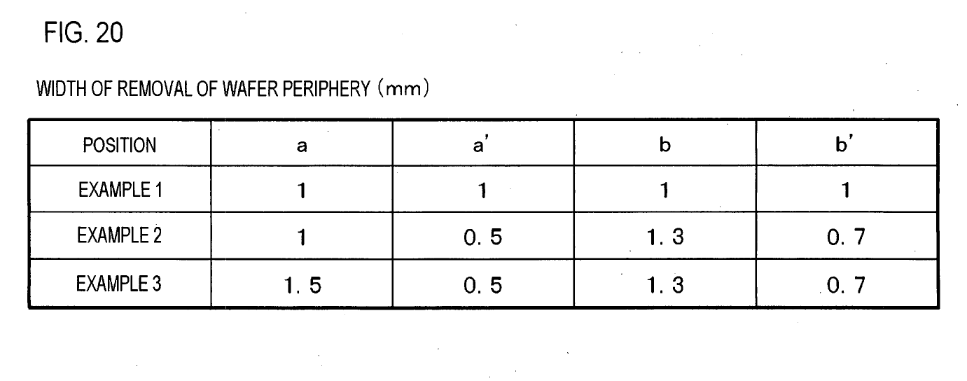

Results are shown in FIG. 20. Example 1 in which the flow rate control of N₂ was effected in four directions was successful in equalizing the widths of removal “a” and “a′” in the X direction and the widths of removal “b” and “b′” in the Y direction, as shown in FIG. 19A. Whereas Example 3 in which the flow rate of N₂ was not controlled was unsuccessful in equalizing the widths of removal of the peripheral portion, showing the width of removal “a” larger than “a′” in the X direction, and the width of removal “b” larger than “b′” in the Y direction, as shown in FIG. 19B. As is clear from the results, Example 1 can equalize the width of removal of the peripheral portion, and consequently can increase the area for element formation.

Even by Example 2, in which the flow rate control of N₂ was effected only at a single site where a width of removal “a” of 1.5 mm was shown in Example 3 under no flow rate control, it was made possible to reduce the width of removal “a” to as small as 1.0 mm, and to reduce the maximum width of removal of the peripheral portion to as small as 1.3 mm, smaller than in Example 3.

In FIGS. 19A and 19B, the center portion surrounded by a dashed line indicates the element formation region, and a cross-hatched portion indicates an etched region. FIG. 19A is a drawing schematically showing the result of Example 1. It can be found that the control herein is successful in equalizing the width of removal of the peripheral portion of the wafer 200. The etched region on the periphery of the wafer 200 and the element formation region do not overlap, so that the element formation region will never be damaged by the etching of the peripheral portion. This makes it possible to increase the number of effective chips obtainable therefrom, and to improve productivity of the semiconductor chips.

On the other hand, FIG. 19B is a drawing schematically showing the result of Example 3. It can be found that the width of removal of the peripheral portion of the wafer 200 is non-uniform. The element formation region is therefore partially etched, and the element formation region is damaged due to such etching of the peripheral portion. This is causative of the reduced number of effective chips obtainable therefrom, and a degraded productivity of the semiconductor chips.

In the above examples, comparison of the width of removal of the peripheral portion of the wafer 200 in the cases where the flow rate of N₂ is controlled and not controlled. In such the comparison, it was shown that by controlling the flow rate of N₂, the width of removal of the peripheral portion of the wafer 200 could be adjusted to be uniform. However, by using the wafer processing apparatus 100 explained in the first embodiment referring to FIG. 3 and FIG. 4, even for the example 3 where the flow rate of N₂ is not controlled, the width of removal of the peripheral portion of the wafer 200 can be more uniform compared with the case where the conventional apparatus which does not have the plurality of supply ports or the partition is used.

As has been described in the above, the control of the flow volume of the etching-interfering gas in the etching of the peripheral portion makes it possible to control the plasma gas generation region, and to increase the element formation region.

The present invention has been described in the above based on the embodiments. It is to be understood by those skilled in the art that these embodiments are merely of exemplary purposes, and allows any modifications in combination of the individual constituents and the individual processes, and that also such modifications fall within a scope of the present invention.

For example, it is also allowable to provide only a single etching-interfering gas introducing duct and a plurality of process gas introducing ducts, so as to control the process gas as being varied in the flow rate by sites. This also contributes to a uniform width of removal of the peripheral portion of the wafer.

Also in the wafer processing apparatus 100 explained in the third embodiment, the fourth embodiment, and the fifth embodiment, it is allowable to align, in the etching process, the next wafer to be etched and to control the flow rate of the gas, by feeding back the displacement of the width of removal of the peripheral portion of the wafer observed by the peripheral removal width observation unit 306, similarly to as described in the second embodiment.

The etching apparatus 300 in the above-described embodiments was configured as having the wafer processing apparatus 100 and the peripheral removal width observation unit 306, whereas it is also allowable to configure the wafer processing apparatus 100 as having a function of the peripheral removal width observation unit 306.

It is apparent that the present invention is not limited to the above embodiments, that may be modified and changed without departing from the scope and spirit of the invention.

What is claimed is:

1. An etching apparatus selectively etching the peripheral portion of a wafer comprising:
a stage on which a wafer is placed;
a process gas supply port through which a process gas for etching said peripheral portion is supplied; and
an etching-interfering gas supply port through which an etching-interfering gas interfering supply of said process gas to the center of said wafer is supplied,
wherein at least either of said process gas supply port and said etching-interfering gas supply port is provided in a multiple way, so as to supply the gas through said plurality of supply ports in a plurality of directions, and so as to independently control supply volume of said gas from said plurality of supply ports.

2. The etching apparatus according to claim 1, wherein said etching-interfering gas supply port is provided in a multiple way, so as to supply the etching-interfering gas through said plurality of etching-interfering gas supply ports in a plurality of directions, and so as to independently control supply volume of said etching-interfering gas from said plurality of etching-interfering gas supply ports.

3. The etching apparatus according to claim 1, wherein both of said process gas supply port and said etching-interfering gas supply port are provided in multiple ways, so as to supply the process gas through said plurality of process gas supply ports and said etching-interfering gas through said plurality of etching-interfering gas supply ports respectively in a plurality of directions, and so as to independently control supply volume of said process gas from said plurality of process gas supply ports and said etching-interfering gas from said plurality of etching-interfering gas supply ports.

4. The etching apparatus according to claim 1, further comprising a partition plate partitioning the gas supplied through said plurality of supply ports.

5. The etching apparatus according to claim 2, further comprising a partition plate partitioning the gas supplied through said plurality of etching-interfering gas supply ports.

6. The etching apparatus according to claim 3, further comprising a partition plate partitioning the gas supplied from said plurality of process gas supply ports and said plurality of etching-interfering gas supply ports.

7. The etching apparatus according to claim 1, further comprising an upper electrode and a lower electrode generating a plasma, and
said stage is configured so as to dispose the wafer between said upper electrode and said lower electrode, and so as to have an in-plane width smaller than that of the wafer placed thereon.

8. The etching apparatus according to claim 2, further comprising an upper electrode and a lower electrode generating a plasma, and
said stage is configured so as to dispose the wafer between said upper electrode and said lower electrode, and so as to have an in-plane width smaller than that of the wafer placed thereon.

9. The etching apparatus according to claim 3, further comprising an upper electrode and a lower electrode generating a plasma, and
said stage is configured so as to dispose the wafer between said upper electrode and said lower electrode, and so as to have an in-plane width smaller than that of the wafer placed thereon.

10. The etching apparatus according to claim 1, further comprising:
a peripheral removal width observation unit which observes width of removal of the peripheral portion of the etched wafer; and
an output unit which outputs the width of removal of said peripheral portion of the etched wafer observed by said peripheral removal width observation unit.

11. The etching apparatus according to claim 10, further comprising a control unit which independently controls the supply volume of said gas supplied through said plurality of supply ports, based on the width of removal of the peripheral portion of the wafer output by said output unit.

12. The etching apparatus according to claim 2, further comprising:
a peripheral removal width observation unit which observes width of removal of the peripheral portion of the etched wafer; and
an output unit which outputs the width of removal of said peripheral portion of the etched wafer observed by said peripheral removal width observation unit.

13. The etching apparatus according to claim 12, further comprising a control unit which independently controls the supply volume of said gas supplied through said plurality of etching-interfering gas supply ports, based on the width of removal of the peripheral portion of the wafer output by said output unit.

14. The etching apparatus according to claim 3, further comprising:
a peripheral removal width observation unit which observes width of removal of the peripheral portion of the etched wafer;
an output unit which outputs the width of removal of said peripheral portion of the etched wafer observed by said peripheral removal width observation unit; and
a control unit which independently controls the supply volume of said gas supplied through said plurality of etching-interfering gas supply ports and said plurality of process gas supply ports, based on the width of removal of the peripheral portion of the wafer output by said output unit.

15. A method of selectively etching the peripheral portion of a wafer, comprising:
selectively etching the peripheral portion of one wafer, using a process gas etching said peripheral portion and an etching-interfering gas interfering supply of said process gas to the center of said wafer,
wherein in said selectively etching, at least either of said process gas and said etching-interfering gas is supplied from a plurality of positions, and so as to independently control supply volume of said gas at each of said positions.

16. The method according to claim 15, intended for successively etching the peripheral portions of a plurality of wafers, further comprising:
observing width of removal of the peripheral portion of the wafer etched in said selectively etching; and
calculating difference in said width of removal occurred in said selectively etching, by comparing said width of removal observed in said observing with a predetermined reference value;
wherein in said selectively etching, supply volume of said gas at each of said positions is independently controlled, based on said difference calculated in said calculating.
